(19) United States
(12) Patent Application Publication
(10) Pub. No.: US 2008/0116487 A1
(43) Pub. Date: May 22, 2008

(54) METHODS OF FABRICATING TRANSISTORS HAVING HIGH CARRIER MOBILITY AND TRANSISTORS FABRICATED THEREBY

(75) Inventors: Byeong-Chan Lee, Gyeonggi-do (KR); Si-Young Choi, Gyeonggi-do (KR); Young-Pil Kim, Gyeonggi-do (JP); Yong-Hoon Son, Gyeonggi-do (KR); In-Soo Jung, Gyeonggi-do (KR); Jin-Bum Kim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/782,237

(22) Filed: Jul. 24, 2007

(30) Foreign Application Priority Data
Nov. 20, 2006 (KR) 10-2006-0114582

(51) Int. Cl. H01L 29/739; H01L 21/336

(52) U.S. Cl. 257/194; 438/290; 438/308; 257/E21.409; 257/E29.194

(57) ABSTRACT

Transistors having a high carrier mobility and devices incorporating the same are fabricated by forming a preliminary semiconductor layer in a semiconductor substrate at both sides of a gate pattern. A source/ drain semiconductor layer having a heterojunction with the semiconductor substrate is formed by irradiating a laser beam onto the preliminary semiconductor layer. The source/drain semiconductor layer is formed in a recrystallized single crystal structure.

### CROSS-REFERENCE TO RELATED APPLICATION

This application claims priority under 35 U.S.C. §119 to Korean Patent Application No. 10-2006-0114582, filed on Nov. 20, 2006, the disclosure of which is hereby incorporated herein by reference in its entirety as if set forth fully herein.

### BACKGROUND OF INVENTION

1. Technical Field

The present invention relates to semiconductor devices, and, more particularly, to methods of fabricating a transistor having a high carrier mobility using a laser beam, methods of fabricating a semiconductor device including a transistor having a high carrier mobility, and transistors and semiconductor devices fabricated thereby.

2. Discussion of the Related Art

As high-speed operations of a semiconductor device and demand for high integration thereof are accelerated, various efforts have been made to develop a highly-integrated semiconductor device and improve the operational characteristics thereof. In particular, because a mobility of an electron and a hole as carriers in a channel of a MOS transistor directly affects a drain current and a switching characteristic, the mobility may be a factor in achieving high integration and high-speed operation of the device.

Among many methods to improve the mobility of the carrier in the channel, a method using a strained Si layer has been widely investigated. The method includes forming a SiGe layer having a crystal lattice larger than that of Si as a virtual substrate on a silicon substrate, and epitaxially growing a single crystal Si layer on the SiGe layer to use as a strained Si layer. However, to compensate for stress resulting from the lattice constant difference between the Si substrate and the SiGe layer, a threading dislocation is propagated to the surface of the strained Si layer due to a high density misfit dislocation introduced to their interface surfaces, which deteriorates an electrical characteristic of the strained Si layer. Therefore, the SiGe layer may be relaxed sufficiently to compensate for the stress described above, and the threading dislocation propagated to the surface of the strained Si layer may be suppressed. To this end, a method has been introduced in which a relaxed SiGe layer having several micrometers in thickness and a uniform Ge concentration on a graded SiGe layer having a vertical Ge concentration gradient is formed, and the strained Si layer is formed on the relaxed SiGe layer.

Generally, the graded SiGe layer is formed using an epitaxial growth technique, such as a molecular beam epitaxy (MBE). The graded SiGe layer may epitaxially grown SiGe using a molecular beam epitaxy technique, while varying a Ge concentration.

As a result, when varying the Ge concentration, the dislocation is generated in the graded SiGe layer. Accordingly, the high density dislocation may be present in the graded SiGe layer, which is grown using a typical epitaxial growth technique, such as the MBE technique. This dislocation may act as a defect in the semiconductor device such as a transistor.

A method which may improve a mobility of carrier in a channel of a transistor is disclosed in U.S. Pat. No. 7,057,216 B1, entitled “High mobility heterojunction complementary field effect transistor and methods thereof” issued to Ouyang, et al.

According to Ouyang, et al., forming a heterojunction source/drain may include etching a Si substrate to thereby form a recessed portion, and forming a SiGe layer which is epitaxially grown in the recessed portion using the molecular beam epitaxy technique or a chemical vapor deposition technique. The recessed region may generate many dislocations in the edge portions in which a bottom surface and side surfaces of the recessed region having different crystal orientations meet with each other. Therefore, the SiGe layer, which is epitaxially grown from the recessed region using the molecular beam epitaxy technique or the chemical vapor deposition technique, may have a high density dislocation.

In addition, because a Ge element in the SiGe layer formed in the recessed region has a generally uniform concentration distribution, the high density misfit dislocation may be generated in the interface surfaces between the SiGe layer and the Si substrate to compensate for the stress resulting from the lattice constant difference between them.

### SUMMARY OF THE INVENTION

In accordance with some embodiments of the present invention, transistors may be fabricated with high carrier mobility. A gate pattern is formed on a semiconductor substrate. A preliminary semiconductor layer is formed in the semiconductor substrate at both sides of the gate pattern. A source/drain semiconductor layer is formed, which has a heterojunction with the semiconductor substrate, by irradiating a laser beam onto the preliminary semiconductor layer. The source/drain semiconductor layer may be formed in a recrystallized single crystal structure.

In other embodiments, forming the source/drain semiconductor layer comprises irradiating a laser beam onto the preliminary semiconductor layer using the gate pattern as a mask to melt the preliminary semiconductor layer.

In still other embodiments, forming the preliminary semiconductor layer comprises etching the semiconductor substrate at both sides of a channel region below the gate pattern to form a recessed region, and filling the recessed region with a semiconductor material.

The gate pattern may comprise a gate dielectric layer, the gate electrode, and a hard mask, which are sequentially stacked, and a gate spacer, which covers sidewalls of the gate dielectric layer, the gate electrode, and the hard mask.

The recessed region may be formed to expose a portion of a bottom surface of the gate spacer.

In still other embodiments, the preliminary semiconductor layer has an amorphous structure, a polycrystalline structure, or a single crystal structure. Further, the preliminary semiconductor layer may comprise a semiconductor material layer comprising Ge. In accordance with various embodiments, the semiconductor material layer may be a SiGe layer or a Ge layer.

When the preliminary semiconductor layer comprises a SiGe layer, the source/drain semiconductor layer may comprises graded SiGe, which has a higher Ge element concentration in a surface portion at both sides of the gate pattern than in a border portion adjacent to the semiconductor substrate.

In still other embodiments, the method further comprises, before forming the gate pattern, forming sequentially a compound semiconductor layer and a strained semiconductor layer having a single crystal structure on the semiconductor substrate using an epitaxial growth method. The compound semiconductor layer comprises a SiGe layer and the strained semiconductor layer may comprise a strained Si layer.

The Ge element in the compound semiconductor layer, which comprises a SiGe layer, may be substantially uniformly distributed.

In still other embodiments, the method further comprises implanting p-type impurity ions into the source/drain semiconductor layer; and activating the implanted impurity ions to form a source/drain region in the source/drain semiconductor layer. The source/drain region extends from the source/drain semiconductor layer to the semiconductor substrate.

In further embodiments of the present invention, a semiconductor device is fabricated that includes transistors having a high mobility. The method comprises forming an isolation layer, which defines a first active region and a second active region in a semiconductor substrate. A compound semiconductor layer and a strained semiconductor layer are sequentially stacked on the second active region, and the compound semiconductor layer and the strained semiconductor layer are formed in a single crystal structure. A first gate pattern is formed on the first active region and a second gate pattern is simultaneously formed on the strained semiconductor layer. The first active region at both sides of the first gate pattern is etched to form a first recessed portion. A first preliminary semiconductor layer is formed, which fills the first recessed portion. A laser beam is irradiated onto the first preliminary semiconductor layer to form a first source/drain semiconductor layer having a heterojunction with the semiconductor substrate. The first source/drain semiconductor layer is formed in a recrystallized single crystal structure.

In still further embodiments of the present invention, the compound semiconductor layer may comprise a SiGe layer, and the Ge in the SiGe layer may be substantially uniformly distributed.

In still further embodiments, the method may further comprise, after forming the compound semiconductor layer, selectively irradiating a laser beam onto the compound semiconductor layer to form a graded compound semiconductor layer having a recrystallized single crystal structure on the second active region, and the graded compound semiconductor layer may comprise a graded SiGe layer, such that the Ge concentration in the graded compound semiconductor layer is higher in an upper region of the graded SiGe layer than in a lower region thereof.

In still further embodiments, the method further comprises etching sequentially the strained semiconductor layer, the compound semiconductor layer, and the second active region at both sides of the second gate pattern to form a second recessed region while etching the first active region on both sides of the first gate pattern, forming a second preliminary semiconductor layer, which fills the second recessed region while forming the first preliminary semiconductor layer, and irradiating a laser beam onto the second preliminary semiconductor layer to form second source/drain semiconductor layer having a heterojunction with the semiconductor substrate in the second active region of the semiconductor substrate while irradiating the laser beam onto the first preliminary semiconductor layer. The second source/drain semiconductor layer being formed in a recrystallized single crystal structure.

Each of the first and second gate patterns may comprise a gate dielectric layer, a gate electrode, and a hard mask, which are stacked sequentially, and a gate spacer, which covers sidewalls of the gate dielectric layer, the gate electrode, and the hard mask.

The first and second recessed regions may be formed to partially expose a bottom surface of the gate spacer of the first gate pattern.

The first and second preliminary semiconductor layers may comprise a semiconductor material layer comprising Ge. The semiconductor material layer may be a SiGe layer or a Ge layer having an amorphous structure, a polycrystalline structure, or a single crystal structure.

When the first and second preliminary semiconductor layers comprise a SiGe layer, each of the first and second source/drain semiconductor layers may have a higher Ge concentration in a surface portion at both sides of the gate pattern than in a border portion adjacent to the semiconductor substrate.

In still further embodiments, forming the first source/drain semiconductor layer may comprise irradiating a laser beam onto the first preliminary semiconductor layer using the first gate pattern as a mask to melt the first preliminary semiconductor layer.

In still further embodiments, the method further comprises implanting p-type first impurity ions into the first source/drain semiconductor layer, implanting p-type or n-type second impurity ions into the second active region at both sides of the second gate pattern, and activating the implanted first and second impurity ions to form a first source/drain region in the first source/drain semiconductor layer and simultaneously form a second source/drain region in the second active region. The first source/drain region is formed to extend from the first source/drain semiconductor layer to the first active region.

In other embodiments of the present invention, a semiconductor device includes transistors having a high carrier mobility. The device comprises an isolation layer in a semiconductor substrate that defines a first active region and a second active region. First and second gate patterns are disposed on the first and second active region. A first source/drain semiconductor layer is disposed in the first active region at both sides of the first gate pattern to form a heterojunction with the first active region. The first source/drain semiconductor layer is a single crystal structure, which is recrystallized by a laser beam.

In still other embodiments, the device further comprises a compound semiconductor pattern and a strained semiconductor pattern, which are interposed between the first active region and the first gate pattern and stacked sequentially. The compound semiconductor pattern may a SiGe layer in which Ge is substantially uniformly distributed, and the strained semiconductor pattern may comprise a strained Si layer.

In still other embodiments, the device may further comprise a graded compound semiconductor layer and a strained semiconductor layer, which are interposed between the second active region and the second gate pattern and stacked sequentially. The graded compound semiconductor layer has a higher Ge concentration in an upper region of the compound semiconductor layer than in the lower region thereof and comprises a graded SiGe layer having a single crystal structure, which is recrystallized by a laser beam. The strained semiconductor layer may comprise a strained Si layer.

In still other embodiments, the first source/drain semiconductor layer may comprise a SiGe layer or a Ge layer. When the first source/drain semiconductor layer comprises a SiGe layer, the first source/drain semiconductor layer may have a higher Ge concentration in a surface portion at both sides of the first gate pattern than in a border portion adjacent to the semiconductor substrate.

In still other embodiments, the device further comprises a p-type first source/drain region, which is disposed in the first source/drain semiconductor layer, and a p-type or n-type second source/drain region, which is disposed in the second active region at both sides of the second gate pattern. The first source/drain region may extend from the first source/drain semiconductor layer to the first active region.

### BRIEF DESCRIPTION OF THE DRAWINGS

Other features of the present invention will be more readily understood from the following detailed description of exemplary embodiments thereof when read in conjunction with the accompanying drawings, in which:

FIGS. 1 to 8 are sectional views illustrating methods of fabricating transistors having high carrier mobility and devices incorporating the same according to various embodiments of the present invention.

### DETAILED DESCRIPTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the description of the figures.

It will be understood that when an element is referred to as being “on” another element, it can be directly on the other element or intervening elements may be present. In contrast, when an element is referred to as being “directly on” another element, there are no intervening elements present. It will be understood that when an element is referred to as being “connected” or “coupled” to another element, it can be directly connected or coupled to the other element or intervening elements may be present. In contrast, when an element is referred to as being “directly connected or coupled” to another element, there are no intervening elements present. Furthermore, “connected” or “coupled” as used herein may include wirelessly connected or coupled. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures were turned over, elements described as being on the “lower” side of other elements would then be oriented on “upper” sides of the other elements. The exemplary term “lower”, can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

In the description, a term “substrate” used herein may include a structure based on a semiconductor, having a semiconductor surface exposed. It should be understood that such a structure may contain silicon, silicon on insulator, silicon on sapphire, doped or undoped silicon, epitaxial layer supported by a semiconductor substrate, or another structure of a semiconductor. And, the semiconductor may be silicon-germanium, germanium, or germanium arsenide, not limited to silicon. In addition, the substrate described hereinafter may be one in which regions, conductive layers, insulation layers, their patterns, and/or junctions are formed.

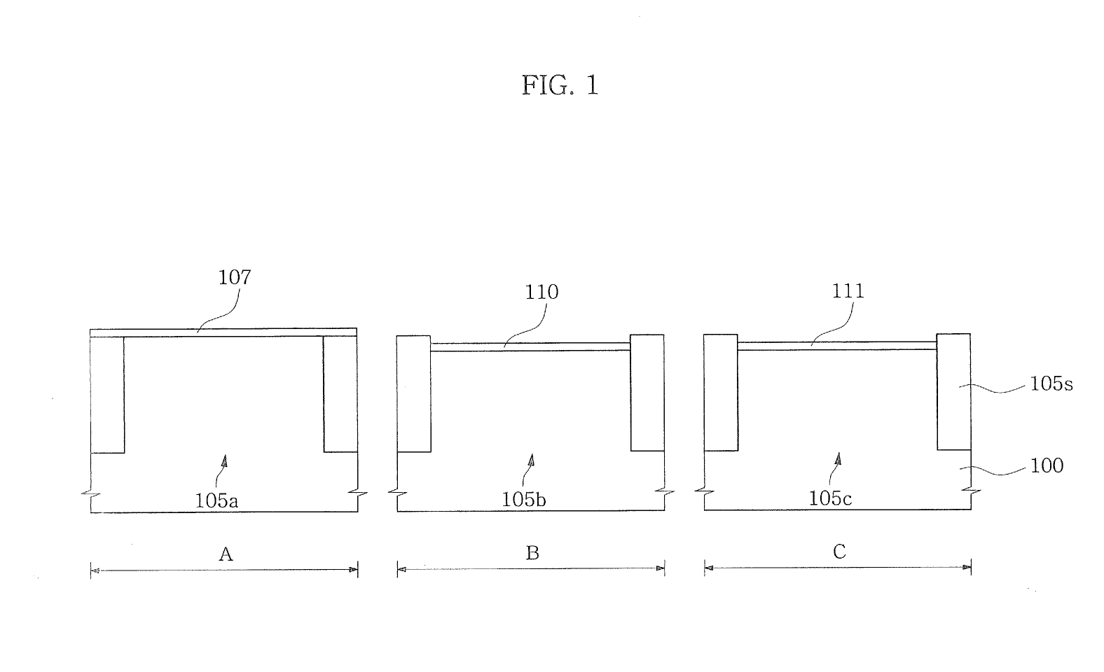

FIGS. 1 to 8 are sectional views illustrating methods of fabricating transistors according to various embodiments of the present invention.

Referring to FIG. 1, a semiconductor substrate 100 having a first transistor region A, a second transistor region B, and a third transistor region C is prepared. The semiconductor substrate 100 may be a silicon substrate having a single crystal structure. An isolation layer 105s is formed in the semiconductor substrate 100 to define a first active region 105a, a second active region 105b, and a third active region 105c. The first active region 105a is formed within the first transistor region A, the second active region 105b is formed within the second transistor region B, and the third active region 105c is formed within the third transistor region C. The isolation layer 105s may be formed using a shallow trench isolation technique.

A protecting layer 107 may be formed on the first active region 105a. The protecting layer 107 may be formed to include a silicon oxide layer and/or a silicon nitride layer.

The second and third active regions 105b and 105c may be etched using the protecting layer 107 and the isolation layer 105s as etch masks, so that the second and third active regions 105b and 105c have their top surfaces positioned at a lower level than that of the first active region 105a. This is because the gate patterns to be formed on the first to third active regions 105a, 105b, and 105c are formed to be positioned at the same level as each other. Etching of the second and third active regions 105b and 105c may be omitted.

A first compound semiconductor layer 110 may be formed on the second active region 105b and, simultaneously, a second compound semiconductor layer 111 may be formed on the third active region 105c. The first and second compound semiconductor layers 110 and 111 may be formed of a SiGe layer having a single crystal structure using an epitaxial growth method. Then, the Ge element in the first and second compound semiconductor layers 110 and 111 formed of SiGe layers may be substantially uniformly distributed.

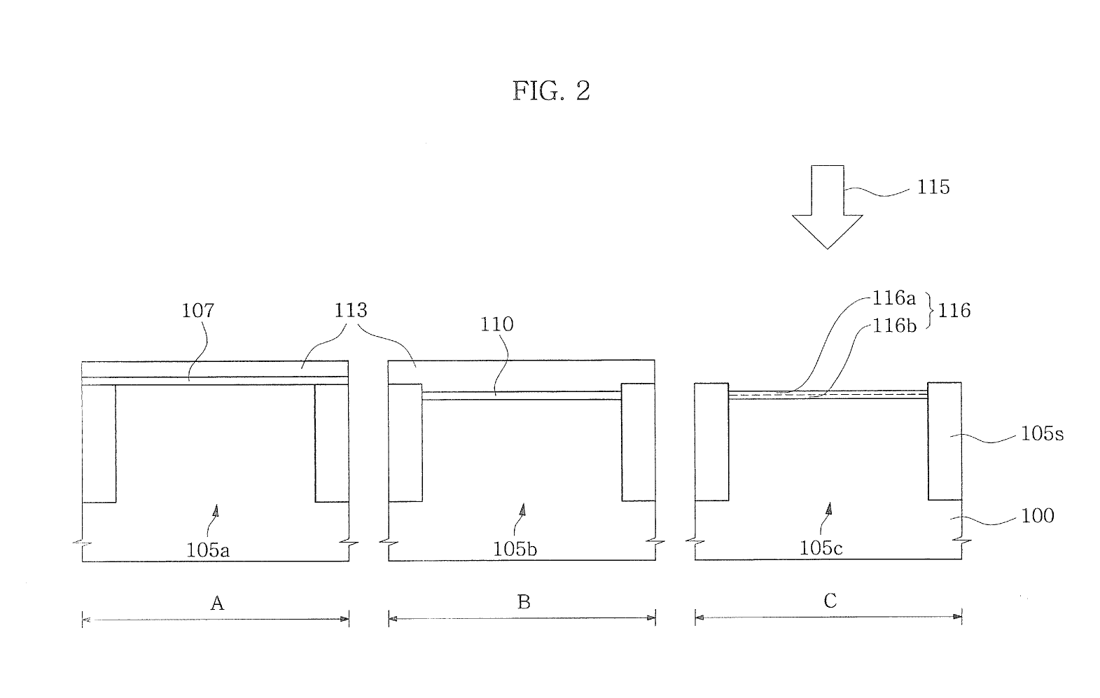

Referring to FIG. 2, a first capping mask 113 may be formed to cover the first active region 105a and the second active region 105b and to expose the second compound semiconductor layer 111 on the third active region 105c. The first capping mask 113 may be formed of a material layer having an etch selectivity with respect to the isolation layer 105s and the semiconductor substrate 100. Further, the first capping mask 113 may be comprise a material capable of reducing or preventing strain in an underlying layer caused by a laser beam by absorbing or reflecting the laser beam. For example, the first capping mask 113 may be formed of a material layer including an amorphous carbon layer.

A graded compound semiconductor layer 116 having a recrystallized single crystal structure may be formed by irradiating a first laser beam 115 on the second compound semiconductor layer 111. The graded compound semiconductor layer 116 may be formed by melting the second compound semiconductor layer 111 using the first laser beam 115 and then recrystallizing it in a single crystal structure. The graded compound semiconductor layer 116 may be formed of a graded SiGe layer. Then, a concentration of Ge element in an upper region 116a of the graded compound semiconductor layer 116, which is formed of the graded SiGe layer, is higher than that in a lower region 116b thereof. For example, the Ge element concentration of the graded compound semiconductor layer 116 may increase from the lower region 116b to the upper region 116a in the graded compound semiconductor layer 116. Therefore, the surface of the upper region 116a of the graded compound semiconductor layer 116 may be relaxed.

Although the graded compound semiconductor layer 116 is formed of the graded SiGe layer, a density of defects, such as vacancy and dislocation in the graded compound semiconductor layer 116, may be reduced or minimized. The reason is because the second compound semiconductor layer 111 is molten using the first laser beam 115 and then is recrystallized to form the graded compound semiconductor layer 116. That is, when the Ge element in the second compound semiconductor layer 111 is redistributed while the second compound semiconductor layer 111 is molten and recrystallized, a defect, such as dislocation, is not generated in the redistribution process of the Ge element.

Further, the defect in the second compound semiconductor layer 111 is cured while the second compound semiconductor layer 111 is molten and recrystallized by the first laser beam 115.

The graded compound semiconductor layer 116 may be formed to have a smooth surface. The reason is because the second compound semiconductor layer 111 is molten using the first laser beam 115 and then is recrystallized, as described above.

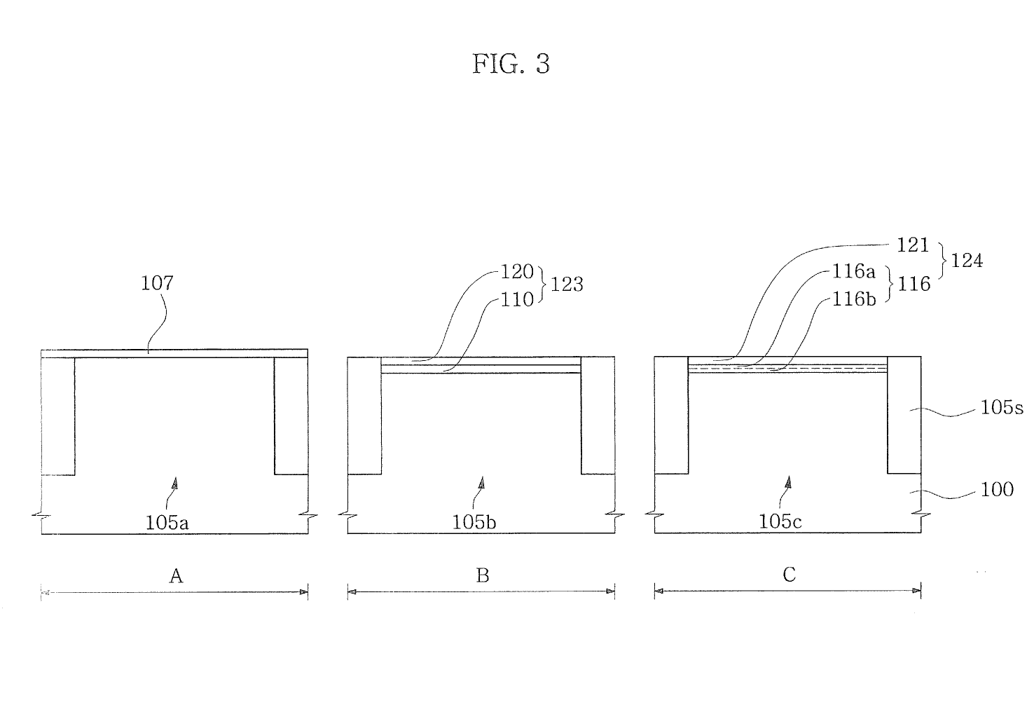

Referring to FIG. 3, the first capping mask 113 may be removed. Subsequently, a first strained semiconductor layer 120 is formed on the first compound semiconductor layer 110, and a second strained semiconductor layer 121 is formed on the graded compound semiconductor layer 116. The first and second strained semiconductor layers 120 and 121 may be formed of strained Si layers using an epitaxial growth method, and the strained Si layer has a single crystal structure. Because the graded compound semiconductor layer 116 is formed of the graded SiGe layer, the second strained semiconductor layer 121 is formed of a tensile strained Si layer.

The first compound semiconductor layer 110 and the first strained semiconductor layer 120 constitute a first channel semiconductor 123, and the graded compound semiconductor layer 116 and the second strained semiconductor layer 121 constitute a second channel semiconductor layer 124.

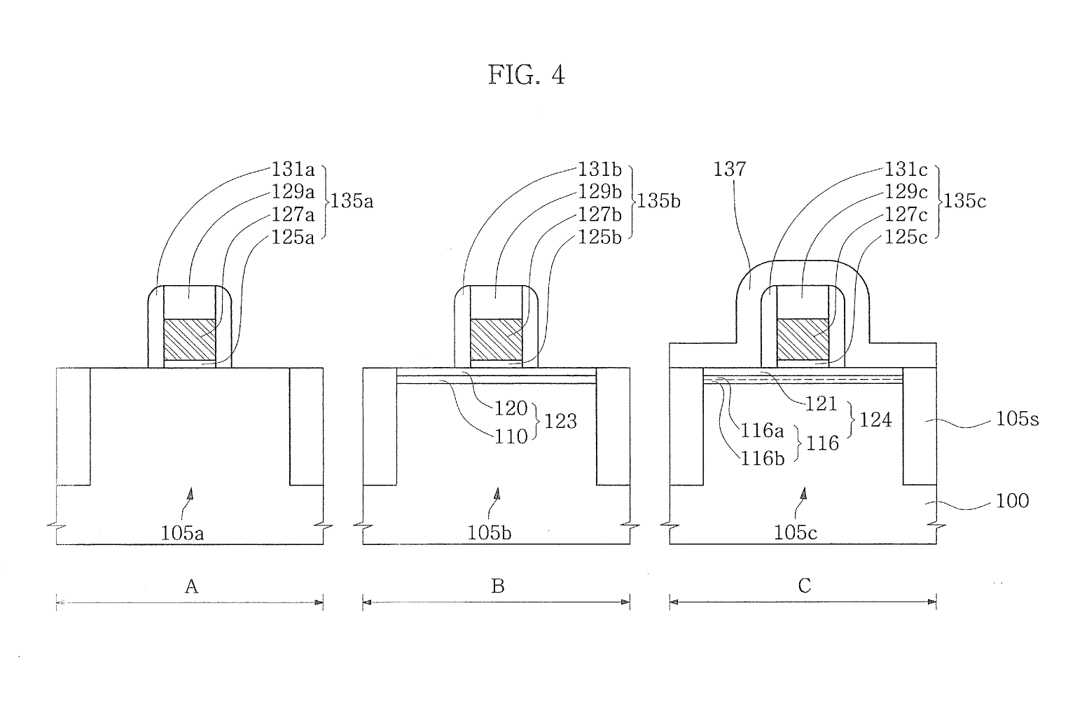

Referring to FIG. 4, the protecting layer 107 may be removed. Then, the surfaces of the first active region 105a, the first strained semiconductor layer 120, and the second strained semiconductor layer 121 may be cleaned.

A first gate dielectric layer 125a, a first gate electrode 127a, and a first hard mask 129a are sequentially formed on the first active region 105a; a second gate dielectric layer 125b, a second gate electrode 127b, and a second hard mask 129b are sequentially formed on the first strained semiconductor layer 120; and a third gate dielectric layer 125c, a third gate electrode 127c and a third hard mask 129c are sequentially formed on the second strained semiconductor layer 121. Each of the first to third gate dielectric layers 125a, 125b, and 125c may be formed of a thermal oxide layer or a high-k dielectric layer. Herein, the high-k dielectric layer may be a dielectric layer comprising a dielectric material having a dielectric constant higher than that of the thermal oxide layer. Each of the first to third gate electrodes 127a, 127b, and 127c may include a polysilicon layer. First to third hard masks 129a, 129b, and 129c may comprise a material capable of reducing or preventing strain in the underlying layer caused by a laser beam by absorbing or reflecting the laser beam. For example, the first to third hard masks 129a, 129b, and 129c are formed to include an amorphous carbon layer.

Then, a first gate spacer 131a is formed to cover the side walls of the first gate dielectric layer 125a, the first gate electrode 127a, and the first hard mask 129a, which are sequentially stacked; a second gate spacer 131b is formed to cover the side walls of the second gate dielectric layer 125b, the second gate electrode 127b, and the second hard mask 129b, which are sequentially stacked; and a third gate spacer 131c is formed to cover the side walls of the third gate dielectric pattern 125c, the third gate electrode 127c, and the third hard mask 129c, which are sequentially stacked. The first to third gate spacers 131a, 131b, and 131c may be simultaneously formed.

The first gate dielectric layer 125a, the first gate electrode 127a, the first hard mask 129a, and the first gate spacer 131a constitute a first gate pattern 135a; the second gate dielectric layer 125b, the second gate electrode 127b, the second hard mask 129b, and the second gate spacer 131b constitute a second gate pattern 135b; and the third gate dielectric layer 125c, the third gate electrode 127c, the third hard mask 129c, and the third gate spacer 131c constitute a third gate pattern 135c.

A second capping mask 137 may be formed, which covers the third active region 105c on the substrate having the first to third gate patterns 135a, 135b, and 135c, but opens a top portion of the first active region 105a and a top portion of the second active region 105b. The second capping mask 137 may be formed of a material layer having an etch selectivity with respect to the isolation layer 105s, the first compound semiconductor layer 110, the first strained semiconductor layer 120, and/or the semiconductor substrate 100. The second capping mask 137 may be formed of a material capable of reducing or preventing strain in the underlying layer caused by the laser beam by absorbing or reflecting it. For example, the second capping mask 137 may be formed to include an amorphous carbon layer.

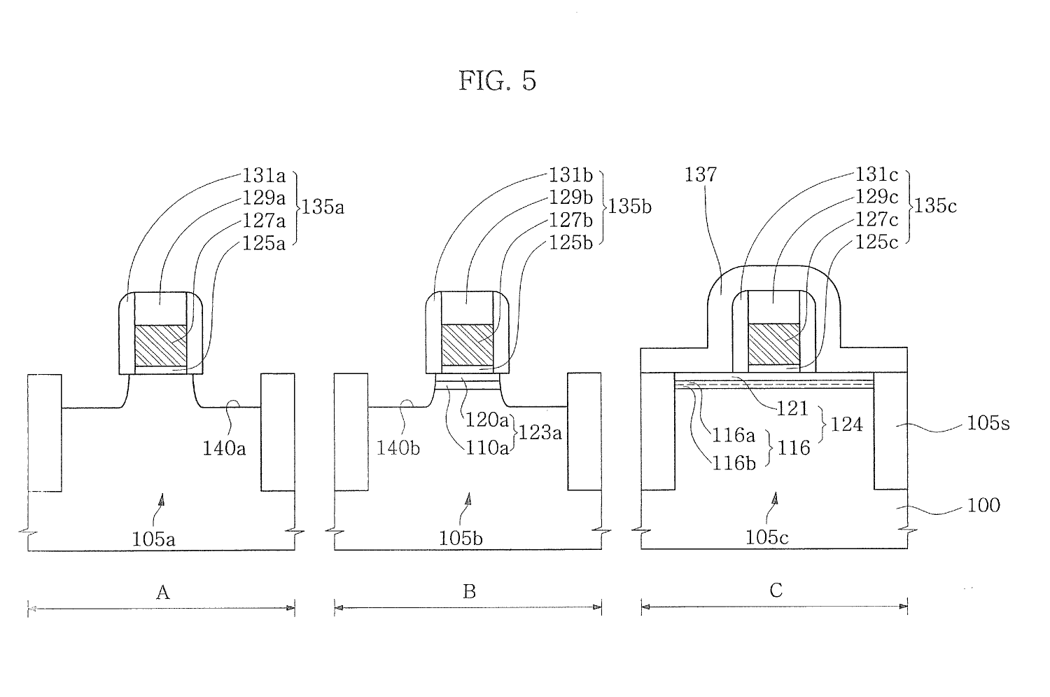

Referring to FIG. 5, a first recessed portion 140a may be formed by etching the first active region 105a on both sides of the first gate pattern 125a using the second capping mask 137, the first and second gate patterns 135a and 135b, and the isolation layer 105s as etch masks, and a second recessed portion 140b may be formed by etching the second active region 105b on both sides of the second gate pattern 135b.

While the second recessed portion 140b is formed, the first compound semiconductor layer 110 (FIG. 4) and the first strained semiconductor layer 120 (FIG. 4) on the second active region 105b are sequentially etched so that a compound semiconductor pattern 110a and a strained semiconductor pattern 120a may be sequentially stacked. The compound semiconductor pattern 110a and the strained semiconductor pattern 120a may form a channel semiconductor pattern 123a.

The first recessed portion 140a is formed to partially expose a bottom surface of the first gate spacer 131a. Likewise, the second recessed portion 140b is formed to partially expose a bottom surface of the second gate spacer 131b. For example, the first and second active regions 105a and 105b are subjected to an anisotropic etch process and/or an isotropic etch process using the second capping mask 137, the first and second gate patterns 135a and 135b, and the isolation layer 105s as etch masks, to thereby form the first and second recessed regions 140a and 140b.

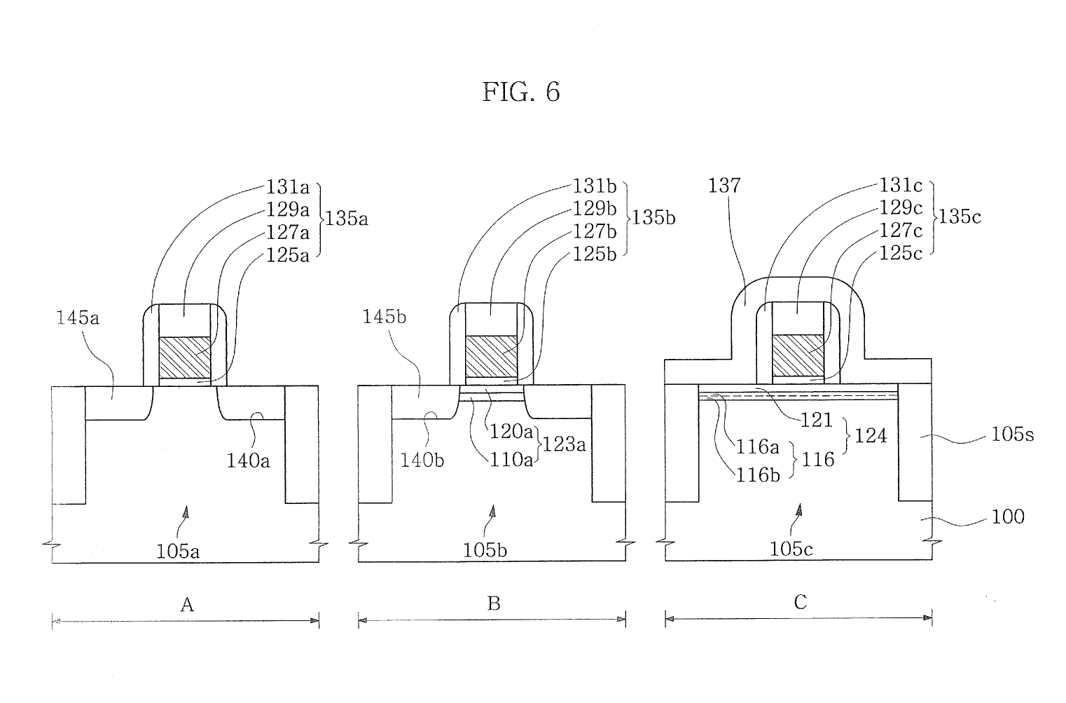

Referring to FIG. 6, a first preliminary semiconductor layer 145a, which fills the first recessed portion 140a, may be formed and, simultaneously, a second preliminary semiconductor layer 145b, which fills the second recessed portion 140b, may be formed. The first and second preliminary semiconductor layers 145a and 145b may be formed so as to be positioned at a level lower than that of the first and second gate patterns 135a and 135b. The first and second preliminary semiconductor layers 145a and 145b may be formed to include a Ge element. For example, the first and second preliminary semiconductor layers 145a and 145b may be formed of a SiGe layer and/or a Ge layer. The first and second preliminary semiconductor layers 145a and 145b may be formed to have a single crystal structure. For example, the first and second preliminary semiconductor layers 145a and 145b may be formed of a semiconductor material layer, such as a SiGe layer and/or Ge layer, which is epitaxially grown from the first recessed portion 140a and the second recessed portion 140b. During the formation of the first and second preliminary semiconductor layers 145a and 145b using the epitaxial growth method, the third active region 105c may be protected by the second capping mask 137.

The first and second preliminary semiconductor layers 145a and 145b may be formed in an amorphous structure or a polycrystalline structure. For example, forming the first and second preliminary semiconductor layers 145a and 145b may include forming a semiconductor material layer having an amorphous structure or a polycrystalline structure that fills the first and second recessed regions 140a and 140b using a chemical vapor deposition method, and etching back the semiconductor material layer so the semiconductor material layer remains in the first and second recessed regions 140a and 140b. Herein, the semiconductor material layer may be formed of a SiGe layer and/or a Ge layer.

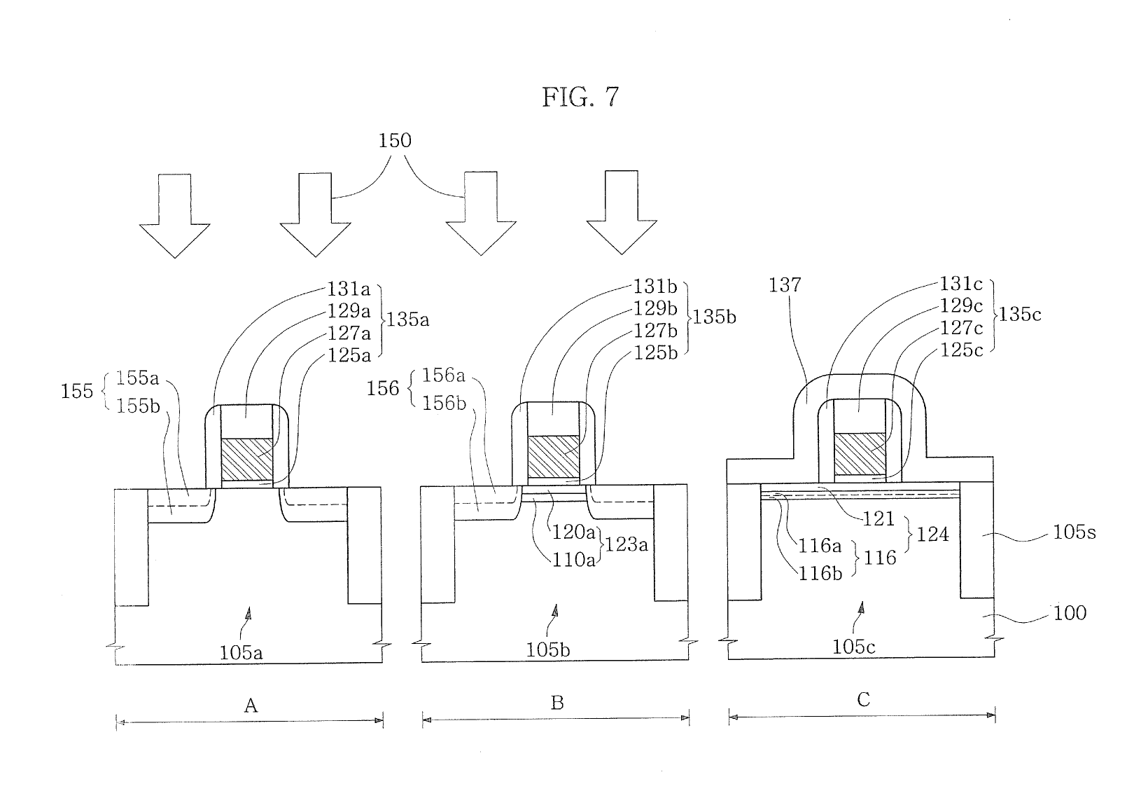

Referring to FIG. 7, a first source/drain semiconductor layer 155 is formed on the first active region 105a by irradiating a second laser beam 150 onto the first preliminary semiconductor layer 145a (FIG. 6) and the second preliminary semiconductor layer 145b using the first and second gate patterns 135a and 135b and the second capping mask 137 as laser masks, and a second source/drain semiconductor layer 156 is formed on the second active region 105b. The first source/drain semiconductor layer 155 may be formed by melting the first preliminary semiconductor layer 145a (FIG. 6) using the second laser beam 150 and then recrystallizing in a single crystal structure. Likewise, the second source/drain semiconductor layer 156 may be formed by melting the second preliminary semiconductor layer 145b (FIG. 6) using the second laser beam 150 and then recrystallizing in a single crystal structure. Therefore, the density of defects, such as vacancy and dislocation, in the first and second source/drain semiconductor layers 155 and 156 may be reduced or minimized. The reason is because the defects, such as vacancy and dislocation, in the first and second preliminary semiconductor layers 145a and 145b (FIG. 6) are cured while the first and second preliminary semiconductor layers 145a and 145b (FIG. 6) are molten and recrystallized by the second laser beam 150.

When the first and second preliminary semiconductor layers 145a and 145b are formed in a single crystal structure using an epitaxial growth method or in a polycrystalline structure using a chemical vapor deposition method, the first and second preliminary semiconductor layers 145a and 145b may be recrystallized in an amorphous structure by implanting Ge element into the first and second preliminary semiconductor layers 145a and 145b having the single crystal structure or the polycrystalline structure. Thereafter, the second laser beam 150 is irradiated onto the first and second preliminary semiconductor layers 145a and 145b, so that the first and second preliminary semiconductor layers 145a and 145b are recrystallized in the single crystal structure.

When the first and second preliminary semiconductor layers 145a and 145b are formed of a SiGe layer, the Ge element concentration of the first source/drain semiconductor layer 155 may be higher in a surface portion 155a on both sides of the first gate pattern 135a than that in a border portion 155b adjacent to the first active region 105a of the semiconductor substrate 100. For example, the Ge element concentration of the first source/drain semiconductor layer 155 may be increased gradually from the border portion 155b to the surface portion 155a. Therefore, the first source/drain semiconductor layer 155 may be formed of the graded SiGe layer. Likewise, the second source/drain semiconductor layer 156 may be formed of a graded SiGe layer having a higher Ge element concentration in a surface portion 156a on both sides of the second gate pattern 135b than that in a border portion 156b adjacent to the second active region 105b of the semiconductor substrate 100. As described above, the first and second preliminary semiconductor layers 145a and 145b (FIG. 6) are formed of a SiGe layer. When the first and second preliminary semiconductor layers 145a and 145b (FIG. 6) are molten, the Ge element in the first and second preliminary semiconductor layers 145a and 145b (FIG. 6) is redistributed. As a result, defect, such as dislocation, may not be generated in the redistribution process of the Ge element. Thus, defects may be reduced or eliminated in the first and second source/drain semiconductor layers 155 and 156. Further, because the first source/drain semiconductor layer 155 has a lower Ge element concentration in the border potion 155b adjacent to the first active region 105a, the stress generated between the first source/drain semiconductor layer 155 and the first active region 105a due to the lattice constant difference between the graded SiGe layer and the silicon substrate may be reduced or minimized. Therefore, the defects and leakage current, which may be generated between the first source/drain semiconductor layer 155 and the first active region 105a, may be reduced or minimized. Likewise, because the stress between the second source/drain semiconductor layer 156 and the second active region 105b may be reduced or minimized, the defects and the leakage current, which may be generated between the second source/drain semiconductor layer 156 and the second active region 105b, may be reduced or minimized.

The first and second source/drain semiconductor layers 155 and 156 can reduce a compressive stress in the channel region below the first and second gate patterns 135a and 135b. As a result, when a PMOS field effect transistor is formed in the first and second transistor regions A and B, a hole mobility of the PMOS field effect transistor can be increased.

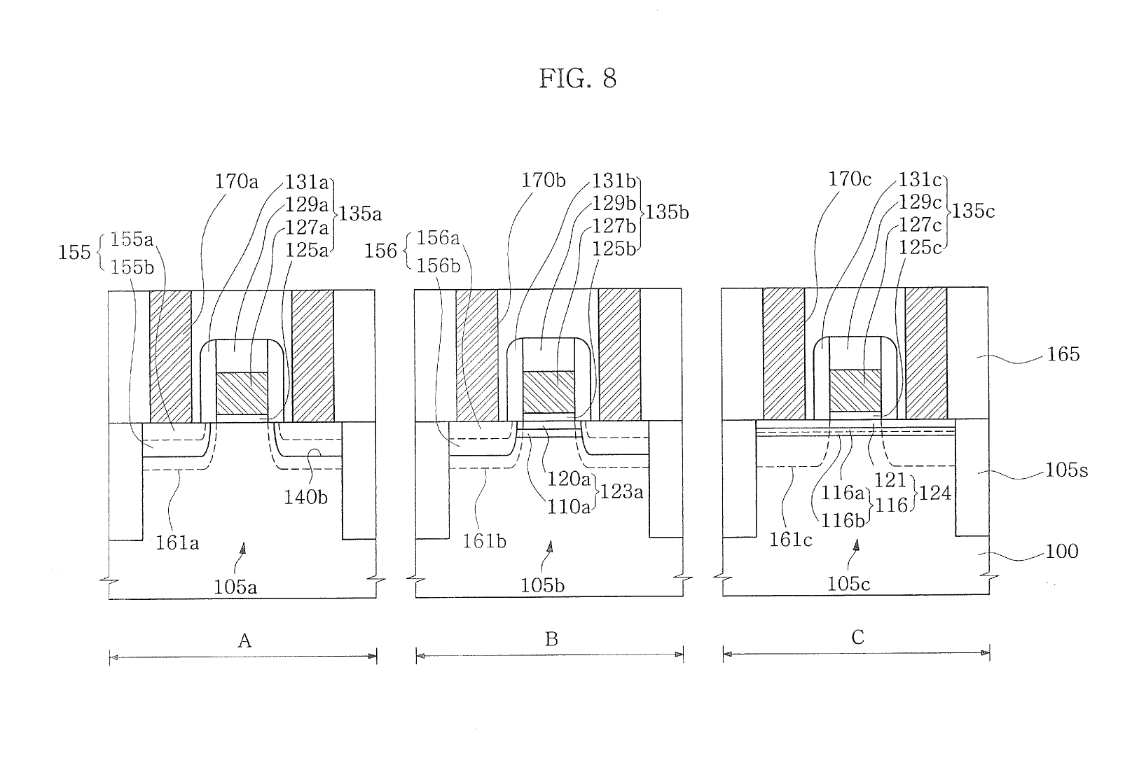

Referring FIG. 8, the second capping mask 137 may be selectively removed. Subsequently, first impurity ions of a first conductivity type are implanted into the first and second source/drain semiconductor layers 155 and 156. First impurity ions of a first conductivity type or second impurity ions of a second conductivity type, which is different from the first conductivity type, are implanted into the second channel semiconductor layer 124 on both sides of the third gate pattern 135c and the third active region 105c. The first conductivity type may be a p type, and the second conductivity type may be an n type.

The implanted impurity ions may be activated. As a result, a first source/drain region 161a may be formed in the first source/drain semiconductor layer 155; a second source/drain region 161b may be formed in the second source/drain semiconductor layer 156; and a third source/drain region 161c may be formed at both sides of the third gate pattern 135c. The first and second source/drain regions 161a and 161b may be p type regions. The third source/drain region 161c may be an n type or p type region.

The first source/drain region 161a may form a junction at the interface between the first source/drain semiconductor layer 155 and the semiconductor substrate 100. Alternately, the first source/drain region 161a may form a junction in a region, which extends from the first source/drain semiconductor layer 155 to the semiconductor substrate 100, so that it may be formed in a structure that encloses the first source/drain semiconductor layer 155. Likewise, the second source/drain region 161b may form a junction at the interface between the second source/drain semiconductor layer 156 and the semiconductor substrate 100, or may form a junction in a region, which extends from the second source/drain semiconductor layer 156 to the semiconductor substrate 100, so that it may be formed in a structure that encloses the second source/drain semiconductor layer 156.

Although not shown in the figures, metal silicide may be formed on the surfaces of the first to third source/drain regions 161a, 161b, and 161c. Further, a self-align silicide process may be performed to form metal silicide on the first to third gate electrodes 127a, 127b, and 127c as well as the surfaces of the first to third source/drain regions 161a, 161b, and 161c. For the silicide process, the first to third hard masks 129a, 129b, and 129c may be removed selectively.

An interlayer insulating layer 165 may be formed on the substrate having the first to third source/drain regions 161a, 161b, and 161c. The interlayer insulating layer 165 may be formed of a silicon oxide layer. While passing through the interlayer insulating layer 165, a first contact structure 170a is formed to be electrically connected to the first source/drain region 161a; a second contact structure 170b is formed to be electrically connected to the second source/drain region 161b; and a third contact structure 170c is formed to be electrically connected to the third source/drain region 161c.

As discussed above, the first and second source/drain semiconductor layers 155 and 156 may be formed of a graded SiGe layer having a higher Ge concentration in the surface portions 155a and 156a. Because the Ge element concentration is higher in the surface portions 155a and 156a than the border portions 155b and 156b, however, a contact resistance between the first and second contact structures 170a and 170b and the first and second source/drain semiconductor layers 155 and 156 may be reduced. This is because the Ge element has an energy band gap that is lower than that of a Si element.

As a result, PMOS field effect transistors whose hole mobilities are different from each other are formed in the first and second transistor regions A and B, and an NMOS field effect transistor or a PMOS field effect transistor may be formed in the third transistor region C.

A semiconductor device, according to some embodiments of the present invention, will be described with reference to FIG. 8. Referring to FIG. 8, an isolation layer 105s is provided in a substrate having a first transistor region A, a second transistor region B, and a third transistor region C. A first active region 105a positioned within the first transistor region A, a second active region 105b positioned within the second transistor region B, and a third active region 105c positioned within the third transistor region C may be defined by the isolation layer 105s.

A first gate dielectric layer 125a, a first gate electrode 127a, and a first hard mask 129a are stacked sequentially on the first active region 105a. A second gate dielectric layer 125b, a second gate electrode 127b, and a second hard mask 129b are stacked sequentially on the second active region 105b. A third gate dielectric layer 125c, a third gate electrode 127c, and a third hard mask 129c are stacked sequentially on the third active region 105c. Each of the first to third gate dielectric layers 125a, 125b, and 125c may be formed of a thermal oxide layer and/or a high-k dielectric layer. The high-k dielectric layer may be a dielectric layer comprising a dielectric material having a dielectric constant higher than that of the thermal oxide layer. Each of the first to third gate electrodes 127a, 127b, and 127c may comprise a polysilicon layer. The first to third hard masks 129a, 129b, and 129c may comprise a material capable of reducing or preventing strain in an underlying layer caused by a laser beam by absorbing or reflecting the laser beam. For example, the first to third hard masks 129a, 129b, and 129c may comprise an amorphous carbon layer.

A first gate spacer 131a may be formed to cover the sidewalls of the first gate dielectric layer 125a, the first gate electrode 127a, and the first hard mask 129a, which are stacked sequentially. A second gate spacer 131b may be formed to cover the sidewalls of the second gate dielectric layer 125b, the second gate electrode 127b, and the second hard mask 129b, which are stacked sequentially. A third gate spacer 131c may be formed to cover the sidewalls of the third gate dielectric pattern 125c, the third gate electrode 127c, and the third hard mask 129c, which are stacked sequentially. The first to third gate spacers 131a, 131b, and 131c may comprise a silicon oxide layer and/or a silicon nitride layer.

The first gate dielectric layer 125a, the first gate electrode 127a, the first hard mask 129a, and the first gate spacer 131a may constitute a first gate pattern 135a; the second gate dielectric layer 125b, the second gate electrode 127b, the second hard mask 129b, and the second gate spacer 131b may constitute a second gate pattern 135b; and the third gate dielectric layer 125c, the third gate electrode 127c, the third hard mask 129c, and the third gate spacer 131c may constitute a third gate pattern 135c. The first to third hard masks 129a, 129b, and 129c in the first to third gate patterns 135a, 135b and 135c may be omitted.

A channel semiconductor pattern 123a may be interposed between the second gate pattern 135b and the second active region 105b. The channel semiconductor pattern 123a may comprise a compound semiconductor pattern 110a and a strained semiconductor pattern 120a, which are stacked sequentially. The compound semiconductor pattern 110a may be formed of a SiGe layer in which a Ge element is substantially distributed, and the strained semiconductor pattern 120a may be formed of a strained Si layer.

A channel semiconductor layer 124 may be formed between the third gate pattern 135c and the third active region 105c. The channel semiconductor layer 124 may comprise a graded compound semiconductor layer 116 and a strained semiconductor layer 121, which are stacked sequentially. The graded compound semiconductor layer 116 may be formed of a graded SiGe layer, in which the Ge element concentration of the graded SiGe layer is higher in an upper region 116a than in a lower region 116b. In addition, the graded compound semiconductor layer 116 may be of a single crystal structure, which is molten by a laser beam and then recrystallized. Therefore, the graded compound semiconductor layer 116 may be of a single crystal structure, which has substantially no defects, such as vacancy and dislocation. The strained semiconductor layer 121 may be formed of a tensile strained Si layer.

A first source/drain semiconductor layer 155 is positioned in the first active region 105a at both sides of the first gate pattern 135a, and forms a heterojunction with the first active region 105a. The first source/drain semiconductor layer 155 may be a single crystal structure, which is recrystallized by a laser beam. The first source/drain semiconductor layer 155 may be positioned at a lower level than the first gate pattern 135a. The first source/drain semiconductor layer 155 may comprise a Ge element. For example, the first source/drain semiconductor layer 155 may be formed of a SiGe layer or a Ge layer.

When the first source/drain semiconductor layer 155 is formed of the SiGe layer, the first source/drain semiconductor layer 155 may have a higher Ge element concentration in a surface portion 155a on both sides of the first gate pattern 135a than in a border portion 155b adjacent to the first active region 105a. Therefore, the first source/drain semiconductor layer 155 may provide a compression stress to the channel region below the first gate pattern 135a.

A second source/drain semiconductor layer 156 is positioned in the second active region 105b at the both sides the second gate pattern 135b, and forms a heterojunction with the second active region 105b. The second source/drain semiconductor layer 156 may be a single crystal structure, which is recrystallized by a laser beam. The second source/drain semiconductor layer 156 may be positioned at a lower level than in the second gate pattern 135b. The second source/drain semiconductor layer 156 may comprise a Ge element. For example, the second source/drain semiconductor layer 156 may be formed of a SiGe layer or a Ge layer.

When the second source/drain semiconductor layer 156 is formed of a SiGe layer, the second source/drain semiconductor layer 156 may have a Ge element concentration, which is higher in a surface portion 156a on both sides of the second gate pattern 135b than in a border portion 156b adjacent to the second active region 105b. Therefore, the second source/drain semiconductor layer 156 may provide a compression stress to a channel region below the second gate pattern 135b.

A first source/drain region 161a of a first conductivity type may be provided in the first source/drain semiconductor layer 155. A junction of the first source/drain region 161 a may match with the interface surface between the first source/drain semiconductor layer 155 and the first active region 105a or may be positioned in a region, which extends from the first source/drain semiconductor layer 155 to the first active region 105a.

A second source/drain region 161b may be provided in the second source/drain semiconductor layer 156. The second source/drain region 161b may have a first conductivity type. A junction of the second source/drain region 161b may match with the interface surface between the second source/drain semiconductor layer 156 and the second active region 105b, or may extend from the second source/drain semiconductor layer 156. A third source/drain region 161c may be provided in the second strained semiconductor layer 121, the graded compound semiconductor layer 116, and the third active region 105c at both sides of the third gate pattern 135c. The third source/drain region 161c may have the first conductivity type or a second conductivity type, which is different from the first conductivity type. The first conductivity type may be a p type, and the second conductivity type may be an n type.

An interlayer insulating layer 165 may be provided on the semiconductor substrate 100 having the first to third source/drain regions 161a, 161b, and 161c. The interlayer insulating layer 165 may comprise a silicon oxide layer. A first contact plug 170a is positioned to pass through the interlayer insulating layer 165 and is electrically connected to the first source/drain region 161a. A second contact plug 170b is positioned to pass through the interlayer insulating layer 165 and is electrically connected to the second source/drain region 161b. A third contact plug 170c is positioned to pass through the interlayer insulating layer 165 and is electrically connected to the third source/drain region 170c.

As a result, PMOS field effect transistors having a high hole mobility may be provided in the first and second transistor regions A and B. An NMOS field effect transistor having a high electron mobility may be provided in the third transistor region C. Therefore, one of the PMOS field effect transistors, which are provided in the first and second transistor regions A and B, and the NMOS field effect transistor, which is provided in the third transistor region C may constitute a CMOS transistor having generally high performance.

As described above, according to various embodiments of the present invention, transistors having a generally high carrier mobility are provided. In particular, source/drain semiconductor layers form the heterojunction with the semiconductor substrate at both sides of the gate pattern and comprise a Ge element having a lattice constant higher than that of a Si element, which constitutes the semiconductor substrate. As a result, a compressive stress may be provided to the channel region below the gate pattern. Because the source/drain semiconductor layer is formed in a single crystal structure, which is recrystallized by a laser beam, it may be possible to reduce or prevent leakage current which may be generated in the heterojunction interface surface between the source/drain semiconductor layer and the semiconductor substrate as well as the leakage current resulting from the defects in the source/drain semiconductor layer.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

That which is claimed:

1. A method of fabricating transistors comprising:
forming a gate pattern on a semiconductor substrate;
forming a preliminary semiconductor layer on the semiconductor substrate at both sides of the gate pattern; and
forming a source/drain semiconductor layer having a heterojunction with the semiconductor substrate by irradiating a laser beam onto the preliminary semiconductor layer, wherein the source/drain semiconductor layer is formed in a recrystallized single crystal structure.

2. The method according to claim 1, wherein forming the source/drain semiconductor layer comprises irradiating a laser beam onto the preliminary semiconductor layer using the gate pattern as a mask to melt the preliminary semiconductor layer.

3. The method according to claim 1, wherein forming the preliminary semiconductor layer comprises:
etching the semiconductor substrate at both sides of a channel region below the gate pattern to form a recessed region; and
filling the recessed region with a semiconductor material.

4. The method according to claim 3, wherein the gate pattern comprises:
a gate dielectric layer, a gate electrode and a hard mask, which are stacked sequentially; and
a gate spacer that covers sidewalls of the gate dielectric layer, the gate electrode and the hard mask.

5. The method according to claim 4, wherein the recessed region is formed to expose a portion of a bottom surface of the gate spacer.

6. The method according to claim 1, wherein the preliminary semiconductor layer comprises a semiconductor material layer comprising Ge; and
wherein the semiconductor material layer is a SiGe layer or a Ge layer having an amorphous structure, a polycrystalline structure, or a single crystal structure.

7. The method according to claim 6, wherein when the preliminary semiconductor layer comprises the SiGe layer; and
wherein the source/drain semiconductor layer comprises a graded SiGe layer, which has a higher Ge concentration in a surface portion at both sides of the gate pattern than in a border portion adjacent to the semiconductor substrate.

8. The method according to claim 1, further comprising before forming the gate pattern:
forming sequentially a compound semiconductor layer and a strained semiconductor layer having a single crystal structure on the semiconductor substrate using an epitaxial growth method;
wherein the compound semiconductor layer comprises a SiGe layer and the strained semiconductor layer comprises a strained Si layer.

9. The method according to claim 8, wherein the Ge in the compound semiconductor layer comprising the SiGe layer is substantially uniformly distributed.

10. The method according to claim 1, further comprising:
implanting p-type impurity ions into the source/drain semiconductor layer; and
activating the implanted impurity ions to form a source/drain region in the source/drain semiconductor layer;
wherein the source/drain region extends from the source/drain semiconductor layer to the semiconductor substrate.

11. A method of fabricating a semiconductor device, comprising:
forming an isolation layer that defines a first active region and a second active region in a semiconductor substrate;
forming a compound semiconductor layer and a strained semiconductor layer, which are stacked sequentially on the second active region, the compound semiconductor layer and the strained semiconductor layer being formed in a single crystal structure;
forming a first gate pattern on the first active region and simultaneously forming a second gate pattern on the strained semiconductor layer;
etching the first active region at both sides of the first gate pattern to form a first recessed portion;
forming a first preliminary semiconductor layer so as to fill the first recessed portion; and
irradiating a laser beam onto the first preliminary semiconductor layer to form a first source/drain semiconductor layer having a heterojunction with the semiconductor substrate;
wherein the first source/drain semiconductor layer is formed in a recrystallized single crystal structure.

12. The method according to claim 11, wherein the compound semiconductor layer comprises a SiGe layer; and
wherein the Ge in the compound semiconductor layer comprising the SiGe layer is substantially uniformly distributed.

13. The method according to claim 11, further comprising:
selectively irradiating a laser beam onto the compound semiconductor layer to form a graded compound semiconductor layer having a recrystallized single crystal structure on the second active region;
wherein the graded compound semiconductor layer comprises a graded SiGe layer, and a Ge concentration in the graded SiGe layer is higher in an upper region of the graded SiGe layer than in a lower region thereof.

14. The method according to claim 11, further comprising:
etching sequentially the strained semiconductor layer, the compound semiconductor layer, and the second active region at both sides of the second gate pattern to form a second recessed region while etching the first active region at both sides of the first gate pattern;
forming a second preliminary semiconductor layer that fills the second recessed region while forming the first preliminary semiconductor layer; and
irradiating a laser beam onto the second preliminary semiconductor layer to form a second source/drain semiconductor layer having a heterojunction with the semiconductor substrate in the second active region while irradiating a laser beam onto the first preliminary semiconductor layer, wherein the second source/drain semiconductor layer is formed in a recrystallized single crystal structure.

15. The method according to claim 14, wherein each of the first and second gate patterns comprises:
a gate dielectric layer, a gate electrode, and a hard mask, which are stacked sequentially; and
a gate spacer which covers sidewalls of the gate dielectric layer, the gate electrode, and the hard mask, which are stacked sequentially.

16. The method according to claim 15, wherein the first and second recessed regions are formed to partially expose a bottom surface of the gate spacer of the first gate pattern.

17. The method according to claim 14, wherein the first and second preliminary semiconductor layers comprise a semiconductor material layer comprising Ge; and
wherein the semiconductor material layer is a SiGe layer or a Ge layer having an amorphous structure, a polycrystalline structure, or a single crystal structure.

18. The method according to claim 17, wherein when the first and second preliminary semiconductor layers comprise the SiGe layer; and
wherein each of the first and second source/drain semiconductor layers has a higher Ge concentration in a surface portion at both sides of the gate pattern than in a border portion adjacent to the semiconductor substrate.

19. The method according to claim 11, wherein forming the first source/drain semiconductor layer comprises irradiating a laser beam onto the first preliminary semiconductor layer using the first gate pattern as a mask to melt the first preliminary semiconductor layer.

20. The method according to claim 11, further comprising:
implanting p-type first impurity ions into the first source/drain semiconductor layer;
implanting p-type or n-type second impurity ions into the second active region at both sides of the second gate pattern; and
activating the implanted first and the second impurity ions to form a first source/drain region in the first source/drain semiconductor layer and simultaneously form a second source/drain region in the second active region;
wherein the first source/drain region is formed to be extended from the first source/drain semiconductor layer to the first active region.

21. A semiconductor device comprising:
an isolation layer formed in a semiconductor substrate to define a first active region and a second active region;
first and second gate patterns disposed on the first and second active regions; and
a first source/drain semiconductor layer in the first active region at both sides of the first gate pattern that forms a heterojunction with the first active region;
wherein the first source/drain semiconductor layer is a single crystal structure which is recrystallized by a laser beam.

22. The device according to claim 21, further comprising:
a compound semiconductor pattern and a strained semiconductor pattern that are interposed between the first active region and the first gate pattern and stacked sequentially;
wherein the compound semiconductor pattern comprises a SiGe layer in which Ge is substantially uniformly distributed, and the strained semiconductor pattern comprises a strained Si layer.

23. The device according to claim 21, further comprising:
a graded compound semiconductor layer and a strained semiconductor layer that are interposed between the second active region and the second gate pattern and stacked sequentially;
wherein the graded compound semiconductor layer has a higher Ge concentration in an upper region than in a lower region and comprises a graded SiGe layer having a single crystal structure, which is recrystallized by a laser beam, and the strained semiconductor layer comprises a strained Si layer.

24. The device according to claim 21, wherein the first source/drain semiconductor layer comprises a SiGe layer or a Ge layer; and
wherein the first source/drain semiconductor layer has a higher Ge concentration in a surface portion at both sides of the first gate pattern than in a border portion adjacent to the semiconductor substrate when the first source/drain semiconductor layer comprises the SiGe layer.

25. The device according to claim 21, further comprising:
a p-type first source/drain region disposed in the first source/drain semiconductor layer; and
a p-type or n-type second source/drain region disposed in the second active region at both sides of the second gate pattern;
wherein the first source/drain region extends from the first source/drain semiconductor layer to the first active region.
